(19) United States
(12) Patent Application Publication
(10) Pub. No.: US 2024/0255816 A1
(43) Pub. Date: Aug. 1, 2024

(54) DISPLAY APPARATUS

(71) Applicant: LG Display Co., Ltd., Seoul (KR)

(72) Inventors: Hyung-Beom SHIN, Paju-si (KR); Dae-Hyun NAM, Paju-si (KR); Se-Eung LEE, Paju-si (KR); Seong-Jun CHO, Paju-si (KR)

(73) Assignee: LG Display Co., Ltd., Seoul (KR)

(21) Appl. No.: 18/540,471

(22) Filed: Dec. 14, 2023

(30) Foreign Application Priority Data
Jan. 31, 2023 (KR) 10-2023-0012956

(51) Int. Cl. G02F 1/1362; G02F 1/1345; H01L 27/12

(52) U.S. Cl. CPC G02F 1/136209; G02F 1/13458; G02F 1/136286; H01L 27/1259; G02F 1/134372; G02F 1/1368

(57) ABSTRACT

A display apparatus can include a display panel including a first substrate and a second substrate, a color filter layer disposed on the first substrate, a plurality of gate lines and a plurality of data lines disposed on the second substrate to define a plurality of subpixels, a thin film transistor disposed in each of the plurality of subpixels on the second substrate, a common electrode and a pixel electrode disposed in each of the plurality of subpixels, and a light absorption layer disposed below each data line to absorb light incident from outside.

### CROSS REFERENCE TO RELATED APPLICATIONS

The present application claims priority to Korean Patent Application No. 10-2023-0012956 filed in Republic of Korea on Jan. 31, 2023, the entire contents of which are hereby expressly incorporated by reference into the present application.

### BACKGROUND

### Field

The present invention relates to a display apparatus that can minimize an area of a bezel of the display apparatus.

### Discussion of the Related Art

Recently, an importance of display apparatuses has increased with the development of multimedia and multimedia technology. For this and other applications, various display apparatuses such as a liquid crystal display apparatus and an organic electroluminescent display apparatus have been developed.

In order for a display apparatus to be used in small portable electronic devices such as a smartphone and a tablet PC, an area of a bezel of the display apparatus needs to be minimized or eliminated. This would realize a relatively large screen even in a small area and can provide an improved appearance for the display apparatus.

### SUMMARY OF THE DISCLOSURE

Accordingly, the present invention is directed to a display apparatus that substantially obviates one or more of the problems due to limitations and disadvantages of the related art.

An advantage of the present invention is to provide a display apparatus which can minimize an area of a bezel of the display apparatus.

An advantage of the present invention is to provide a display apparatus which can prevent image quality from being deteriorated due to reflection of an external light.

Additional features and advantages of the invention will be set forth in the description which follows, and in part will be apparent from the description, or can be learned by practice of the invention. These and other advantages of the invention will be realized and attained by the structure particularly pointed out in the written description and claims hereof as well as the appended drawings.

To achieve these and other advantages and in accordance with the purpose of the present invention, as embodied and broadly described herein, a display apparatus includes a display panel including a first substrate and a second substrate, a backlight unit facing the first substrate and supplying light to the display panel, a color filter layer disposed on the first substrate, a plurality of gate lines and a plurality of data lines disposed on the second substrate to define a plurality of subpixels, a thin film transistor disposed in each of the plurality of subpixels on the second substrate, a common electrode and a pixel electrode disposed in each of the plurality of subpixels, and a light absorption layer disposed below the data line to absorb light incident from an outside.

According to an aspect of the present invention, a display apparatus includes a display panel including a first substrate and a second substrate; a color filter layer disposed on the first substrate; a plurality of gate lines and a plurality of data lines disposed on the second substrate to define a plurality of subpixels; a thin film transistor disposed in each of the plurality of subpixels on the second substrate; a common electrode and a pixel electrode disposed in each of the plurality of subpixels; and a light absorption layer disposed below each data line to absorb light incident from outside.

According to an aspect of the present invention, a display apparatus includes a substrate including a subpixel region and a pad region adjacent to the subpixel region; a subpixel disposed in the subpixel region; a light absorption layer and a gate electrode of the subpixel separated from each other, and disposed in the subpixel region of the substrate; a data line disposed on the light absorption layer; and a gate pad separated from the light absorption layer, and disposed in the pad region of the substrate, wherein the gate electrode, the light absorption layer and the gate pad are formed of a same material in a same process, and wherein each of the gate electrode, the light absorption layer and the gate pad includes a first metal layer and a second metal layer disposed on the first metal layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a view schematically illustrating a display apparatus according to an aspect of the present invention;

FIG. 2 is a view illustrating an external light being reflected in a display apparatus, which is indicated by an arrow line;

FIG. 3 is a plan view of a display apparatus according to a first embodiment of the present invention;

FIG. 4 is a cross-sectional view illustrating a display apparatus according to the first embodiment of the present invention;

FIGS. 5A to 5I are views illustrating a method of manufacturing a display apparatus according to the first embodiment of the present invention; and

FIG. 6 is a cross-sectional view illustrating a display apparatus according to a second embodiment of the present invention.

### DETAILED DESCRIPTION OF THE EMBODIMENTS

Advantages and features of various aspects of the present invention and methods of achieving them can be apparent with reference to the embodiments described below in detail with the accompanying drawings. However, the present invention is not limited to the embodiments disclosed below, but can be realized in a variety of different forms, and only these embodiments allow the present invention to be complete. The present invention can be provided to fully inform the scope of the invention to the skilled in the art of the present invention, and the present invention can be defined by the scope of the claims.

The term “exemplary” is used to mean an example, and is interchangeably used with the term “example”. Further, embodiments are example embodiments and aspects are example aspects. Any implementation described herein as an “exemplary” or “example” is not necessarily to be construed as preferred or advantageous over other implementations. Also, “embodiment” is “embodiment” of the present invention. Further, the term “invention” can be interchangeably used with the term “disclosure”.

The shapes, sizes, proportions, angles, numbers, and the like disclosed in the drawings for explaining the embodiments of the present invention are illustrative, and the present invention is not limited to the illustrated matters. The same reference numerals can refer to the same components throughout the description.

Furthermore, in describing the present invention, if it is determined that a detailed description of the related known technology unnecessarily obscure the subject matter of the present invention, the detailed description thereof can be omitted. When ‘comprising’, ‘including’, ‘having’, ‘consisting’, and the like are used in this invention, other parts can be added unless ‘only’ is used. When a component is expressed in the singular, cases including the plural are included unless specific statement is described.

In interpreting the components, even if there is no separate explicit description, it is interpreted as including a margin range.

In the case of a description of a positional relationship, for example, when the positional relationship of two parts is described as ‘on’, ‘over’, ‘above’, ‘below’, ‘beside’, ‘under’, and the like, one or more other parts can be positioned between such two parts unless ‘right’ or ‘directly’ is used.

In the case of a description of a temporal relationship, for example, when a temporal precedence is described as ‘after’, ‘following’, ‘before’, and the like, cases that are not continuous can be included unless ‘directly’ or ‘immediately’ is used.

Respective features of various embodiments of the present invention can be partially or wholly connected to or combined with each other and can be technically interlocked and driven variously, and respective embodiments can be independently implemented from each other or can be implemented together with a related relationship.

In describing components of the present invention, terms such as first, second, A, B, (a), (b) and the like can be used. These terms are only for distinguishing the components from other components, and an essence, order, order, or number of the components is not limited by the terms. Further, when it is described that a component is “connected”, “coupled” or “contact” to another component, the component can be directly connected or contact the another component, but it should be understood that other component can be “interposed” between the components.

It will be understood that, although the terms “first,” “second,” or the like can be used herein to describe various elements, these elements should not be limited by these terms, for example, to any particular order, sequence, precedence, or number of elements. These terms are only used to distinguish one element from another. For example, a first element could be termed as a second element, and, similarly, a second element could be termed as a first element, without departing from the scope of the present disclosure.

Further, “at least one” should be understood to include all combinations of one or more of associated components. For example, a meaning of “at least one of first, second, and third components” means not only the first, second, or third component, but also all combinations of two or more of the first, second and third components.

In this invention, a “display apparatus” can include a display apparatus in a narrow sense, such as a display module including a display panel and a driving portion for driving the display panel. Furthermore, the “display apparatus” can include a complete product or final product including a display module which is a notebook computer, a television, a computer monitor, an automotive display or equipment display including other type of vehicle, or a set electronic device or set device or set apparatus such as a mobile electronic device which is a smart phone, an electronic pad or the like.

Therefore, the apparatus of this invention can include a display apparatus itself such as a display module, and an application product or a set device that is an end-user device, including a display module. Further, the term “apparatus” is interchangeably used with the term “device.”

Hereinafter, embodiments of the present invention are described in detail with reference to the drawings. All the components of each display apparatus according to various embodiments of the present invention are operatively coupled and configured.

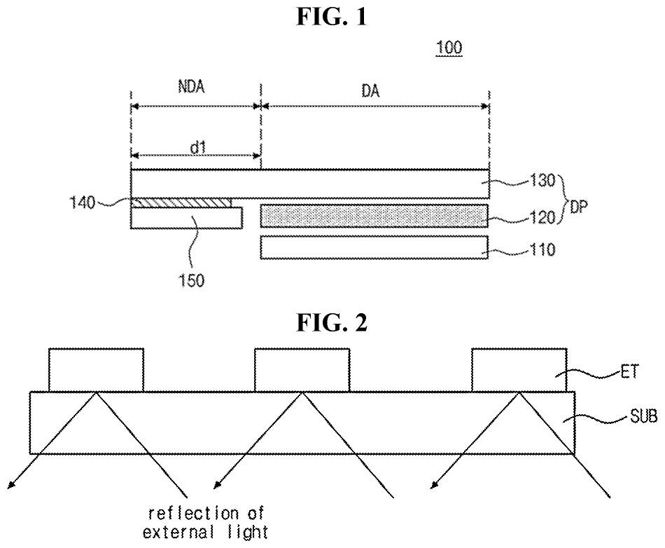

FIG. 1 is a view schematically illustrating a display apparatus according to an aspect of the present invention.

As shown in FIG. 1, a display apparatus 100 according to an aspect of the present invention can include a liquid crystal panel DP including a color filter substrate 120, an array substrate 130, and a liquid crystal layer disposed between the color filter substrate 120 and the array substrate 130. A backlight unit 110 that supplies light to the liquid crystal panel DP can be disposed below the liquid crystal panel DP, and an image can be realized by controlling transmission of light supplied from the backlight unit 110 in the liquid crystal layer. The color filter substrate 120, the array substrate 130 and the backlight unit 110 include various known elements, such as pixels composed of sub-pixels, data lines, gate lines, color filters, a black matrix, etc.

The display panel DP includes a display area (or non-active area) DA for displaying images, and a non-display area (or non-active area) NDA in which images may not be displayed. The non-display area NDA can surround the display area DA entirely or only in part(s). Multiple non-display areas NDAs and/or multiple display areas DAs can be disposed in the display panel DP. Further, different shapes can be used for the display panel DP, the display area DA, and the non-display area NDA.

In a related art liquid crystal display apparatus, a backlight unit, an array substrate, and a color filter substrate are arranged in that order from the bottom.

However, in the display apparatus 100 according to the embodiments of the present invention, the backlight unit 110, the color filter substrate 120, and the array substrate 130 are arranged in that order. In other words, compared to the related art structure, in the structure of the present invention, the color filter substrate 120 and the array substrate 130 are arranged in the reverse order, so that the array substrate 130 becomes a screen on which images are displayed.

With this configuration, a printed circuit board (PCB) 140 formed on one side of the array substrate 130 to apply a driving signal that controls the transmission of light can be directly attached to a back surface of the array substrate 130. In other words, the printed circuit board 140 can be formed directly on the back surface of the array substrate 130 facing the liquid crystal layer, and a driving circuit 150 can be mounted on the printed circuit board 140. For instance, the PCB 140 is disposed between the array substrate 130 and the driving circuit 150.

Thus, in the present invention, there is no need to attach one end of the printed circuit board 140 to one side of a front surface of the array substrate 130 and bend the printed circuit board 140 to the back surface of the array substrate 130 as (which occurs in the related art liquid crystal display apparatus). Therefore, workability is improved and thus tact time can be reduced, and the non-display region NDA can be formed only in a region d1 where various lines and pads are formed. As a result, the display apparatus 100 with a narrow bezel region can be provided in the present application.

On the other hand, as shown in FIG. 2, in the display apparatus 100, since a transparent substrate SUB of the array substrate 130 is disposed on the front side (e.g., on the front side of the display apparatus 100), an external light passes through the transparent substrate SUB and then is reflected by a metal layer ET that forms various lines such as gate lines and data lines and various electrodes such as source and drain electrodes of thin film transistors formed inside the array substrate 130. This can cause the quality of display image to deteriorate.

According to an aspect of the present invention, by minimizing light reflection on the array substrate 130 disposed on the front side of the display apparatus 100, it is possible to minimize degradation of display image quality. Hereinafter, the present invention is described in detail with reference to the attached drawings.

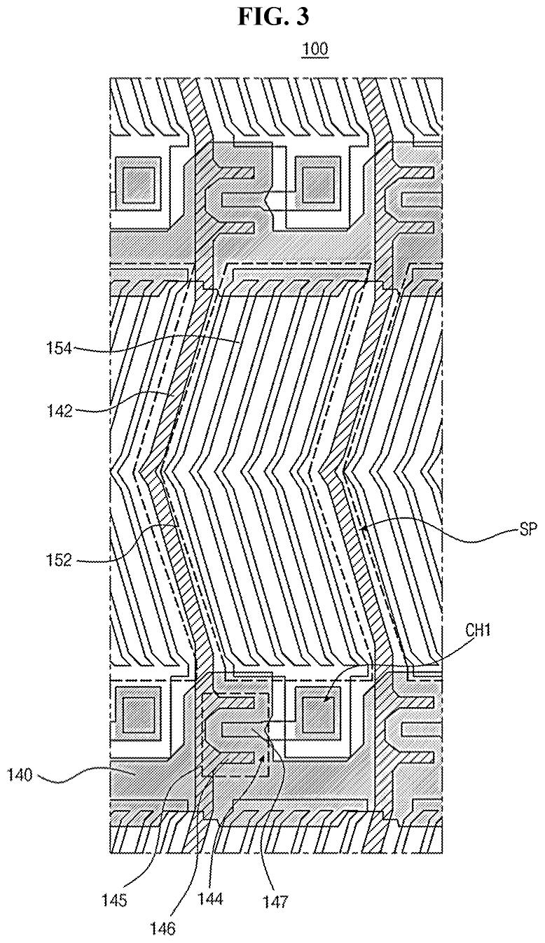

FIG. 3 is a plan view of a display apparatus according to a first embodiment of the present invention. The plan view of FIG. 3 is an example of a portion of the display apparatus, which can include a plurality of subpixels having such configuration.

As shown in FIG. 3, in the display apparatus 100 according to the first embodiment of the present invention, a gate line 140 and a data line 142 can be arranged vertically and horizontally to define a subpixel SP. In the actual display apparatus 100, the gate lines 140 and the data lines 142 are arranged in a n*m matrix (where n and m are natural numbers) to define a plurality of subpixels SP, but in the drawings, for convenience of explanation, one subpixel SP is shown. Further, the data lines and gate lines can extend in substantially vertical and horizontal directions, but can extend differently.

A thin film transistor can be disposed in each subpixel SP. The thin film transistor can include a gate electrode 144 disposed in the gate line 140, a semiconductor layer 145 disposed on the gate electrode 144, and a source electrode 146 and a drain electrode 147 disposed on the semiconductor layer 145. In the drawing, the gate electrode 144 is formed integrally with the gate line 140, but the gate electrode 144 can be formed to protrude from the gate line 140 toward the subpixel SP.

A common electrode 152 and a pixel electrode 154 can be disposed in each subpixel SP. The common electrode 152 can be formed approximately throughout the subpixel SP. In other words, the common electrode 152 can be formed in the same shape as the subpixel SP and be disposed throughout the subpixel SP. The pixel electrode 154 can have a strip shape with a set width, and a plurality of pixel electrodes 154 can be arranged in each subpixel SP and be in parallel with the data line 142.

Alternatively, the pixel electrode 154 can be formed in the same shape as the subpixel SP and be formed over the entire region of the subpixel SP, and the common electrode 152 can be formed in a strip shape with a set width and be arranged in parallel with the data line 142.

The pixel electrode 154 can be electrically connected to the drain electrode 147 of the thin film transistor through a contact hole CH1. Further, as described in detail later, the common electrode 152 and the pixel electrode 154 can be disposed with an insulating layer interposed therebetween.

As a scan signal is applied to the gate line 140, the thin film transistor is turned on, and an image signal supplied through the data line 142 is applied to the pixel electrode 154 through the thin film transistor. Accordingly, a fringe field is formed between the common electrode 152 and the pixel electrodes 154, and liquid crystal molecules of the liquid crystal layer are driven by the fringe electric field to control the transmittance of light passing through the liquid crystal layer, thereby enabling image display.

The data line 142 can be bent once at a set angle from a center (or a set location) of the subpixel SP. When viewed as a whole of the display apparatus 100, each data line 142 can be formed in a zigzag shape. For example, the data line 142, which is bent once at the center of the subpixel SP, can be formed symmetrically with respect to the center of each subpixel SP.

As such, as the data line 142 is formed symmetrically with respect to the center of the subpixel SP, the subpixel SP is divided into two domains. When the fringe field is produced between the common electrode 152 and the pixel electrode 154, the electric field directions in the two domains are symmetrical to each other, thereby improving the viewing angle characteristics of the display apparatus 100.

In this regard, as a variation, if the viewing angle characteristics can be improved, the subpixel SP can include three or more domains, where the data line 142 and the pixel electrode 154 can be bent twice or more in each subpixel SP. Alternatively, the data line 142 and the pixel electrode 154 may not be bent in the subpixel SP.

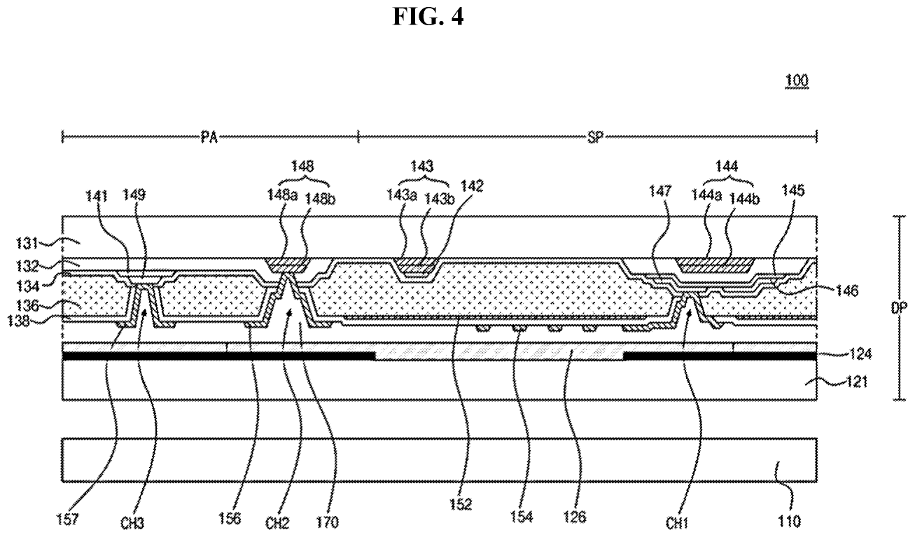

Meanwhile, in the display apparatus 100 according to the first embodiment of the present invention, a metal layer 143 (e.g., see FIG. 4) can be disposed below the data line 142. The metal layer 143 can be disposed along (extend with) the data line 142, but the metal layer 143 may not be disposed near the thin film transistor and in an intersection region between the data line and the gate line 140.

The metal layer 143 can serve to absorb an external light and prevent the external light from being reflected on the data line 142. The metal layer 143 can be made of a metal material with good conductivity and low reflection characteristics. The metal layer 143 can be electrically connected to the data line 142 in a floating state.

Meanwhile, a gate pad can be formed at an end of the gate line 140 so that the scan signal can be applied to the gate line 140 through the gate pad, and a data pad can be formed at an end of the data line 142 so that the image signal can be applied to the data line 142 through the data pad.

FIG. 4 is a cross-sectional view specifically illustrating a structure of a display apparatus according to the first embodiment of the present invention. The cross-section view shown in FIG. 4 is an example of the portion of the display apparatus, which can include the plurality of subpixels SP having such configuration.

As shown in FIG. 4, the display apparatus 100 can include the display panel DP including the subpixel SP and a pad region PA disposed outside or adjacent to the subpixel SP, and a backlight unit 110. The backlight unit 110 can be disposed below the display panel DP and supplies light to the display panel DP. A region of the subpixel SP can also be referred to as a subpixel region SP.

The backlight unit 110 can include one or more of various light sources. For example, the backlight unit 110 can be configured with a fluorescent lamp such as a cold cathode fluorescent lamp or an external electrode fluorescent lamp, or a light emitting diode (LED), but not limited thereto.

The display panel DP can include a first substrate 121 and a second substrate 131. The first substrate 121 and the second substrate 131 can be made of a hard transparent material such as glass, or a flexible material such as plastic. The plastic can include at least one of polyimide, polymethylmethacrylate, polyethylene terephthalate, polyethersulfone, and polycarbonate, but not limited thereto.

A black matrix 124 and a color filter layer 126 can be formed on the first substrate 121. The black matrix 124 can be formed in the pad region PA and a boundary region between the subpixels SP, and the color filter layer 126 can be formed in the subpixel SP.

The black matrix 124 can be made of a metal material such as Cr or CrO, or can be made of black resin, but not limited thereto. The color filter layer 126 can be made of a resin material containing pigment or dye, but not limited thereto. The color filter layer 126 can include a red color filter layer, a green color filter layer, and a blue color filter layer, but not limited thereto. For instance, the color filter layer 126 can further include a white color filter layer.

The thin film transistor can be formed in the subpixel SP of the second substrate 121. The thin film transistor can include a gate electrode 144 formed on an upper surface (or inner surface) of the second substrate 131, a gate insulating layer 132 formed on the gate electrode 144, a semiconductor layer 145 formed on the gate insulating layer 132, and a source electrode 146 and a drain electrode 147 formed on the semiconductor layer 145 and spaced apart from each other by a predetermined distance.

The gate electrode 144 can be formed of a first gate metal layer 144a and a second gate metal layer 144b on the first gate metal layer 144a. The first gate metal layer 144a can be made of a low reflective metal material with good light absorptance. For example, the first gate metal layer 144a can be made of a composite material of a metal such as molybdenum (Mo) or molybdenum oxide (MoOx) and a ceramic material such as Nb2O5 (niobium pentoxide or niobium oxide).

Here, Mo and MoOx have good absorption characteristics with an extinction coefficient (k) of about 3˜4, but etching characteristics may not be good. Therefore, if forming the first gate metal layer 144a with Mo or MoOx only, reflection of external light can be minimized, but since the etching characteristics can be poor, it is practically difficult to form the first gate metal layer 144a by patterning the metal. On the other hand, Nb2O5 has poor light absorption characteristics but good etching characteristics.

Thus, in the first embodiment of the present invention, the first gate metal layer 144a can be formed with a material with good low reflection characteristics and good etching characteristics by synthesizing the metal such as Mo or MoOx and the ceramic material such as Nb2O5. According to an aspect of the present invention, the first gate metal layer 144a, which is made by combining the metal such as Mo or MoOx and the ceramic material such as Nb2O5, can have an extinction coefficient (k), where 0.6<k<1.2 for example.

The second gate metal layer 144b can be made of aluminum (Al), gold (Au), silver (Ag), or copper (Cu) with good conductive characteristics, but not limited thereto.

As such, in the display apparatus 100 according to the first embodiment of the present invention, since the lower layer (first gate metal layer) 144a of the gate electrode 144 formed on the second substrate 131 on the side where an image is displayed is made of a material with low reflection characteristics, reflection of external light by the gate electrode 144 can be minimized, thereby preventing deterioration of image quality due to the reflection of external light.

The gate insulating layer 132 can be formed on the gate electrode 144 of the subpixel SP and in the pad region PA. The gate insulating layer 132 can be configured in a single layer or multiple layers using an inorganic material such as silicon nitride (SiNx) or silicon oxide (SiOx), but not limited thereto.

The semiconductor layer 145 can be made of an amorphous semiconductor or a polycrystalline semiconductor. For example, a polycrystalline semiconductor can be made of low temperature polysilicon (LTPS) with high mobility, but not limited thereto.

Alternatively, the semiconductor layer 145 can be made of an oxide semiconductor. For example, the semiconductor layer 145 can include indium-gallium-zinc-oxide (IGZO), indium-zinc-oxide (IZO), indium-gallium-tin-oxide (IGTO), and indium-gallium-oxide (IGO), but not limited thereto. The semiconductor layer 145 can include a channel region in a central portion and source and drain regions on both sides.

The source electrode 146 and the drain electrode 147 can be configured in a single layer or multiple layers using molybdenum (Mo), aluminum (Al), chromium (Cr), gold (Au), titanium (Ti), nickel (Ni), neodymium (Nd), copper (Cu), or an alloy thereof, but not limited thereto.

A data line 142 can be disposed in the subpixel SP and a metal layer 143 can be disposed below the data line 142 (i.e., from the perspective of the first substrate 121 being the front/top). The data line 142 can be formed of the same material as the source electrode 146 and drain electrode 147 of the thin film transistor. The metal layer 143 can be configured with a first metal layer 143a and a second metal layer 143b. At this time, the first metal layer 143a can be made of the same material as the first gate metal layer 144a, and the second metal layer 143b can be made of the same metal as the second gate metal layer 144b.

As such, according to an aspect of the present invention, the metal layer 143 made of Mo or MoOx with low reflection characteristics and Nb2O5 can be formed on the lower surface of the data line 142, so that the metal layer 143 can absorb the external light incident on the data line 142 (e.g., see the external light in FIG. 2). Thus, the reflection of external light on the data line 142 can be minimized, thereby preventing degradation of image quality due to the reflection of external light.

Meanwhile, since the metal layer 143 blocks the incidence of external light or absorbs light, it can be referred to as a light blocking layer or a light absorption layer.

From the perspective of the first substrate 121 being the front/top (which will be used in the following description), a gate pad 148 and a data pad 149 can be disposed in the pad region PA. The gate pad 148 can be formed on the upper surface of the second substrate 131, and the data pad 149 can be formed on the gate insulating layer 132. The gate pad 148 can be composed of a first gate pad layer 148a and a second gate pad layer 148b. The first gate pad layer 148a can be formed of the same material and in the same process as the first gate metal layer 144a and the first metal layer 143a, whereas the second gate pad layer 148b can be formed of the same material and in the same process as the second gate metal layer 144b and the second metal layer 143b.

The data pad 149 can be formed of the same metal and in the same process as the source electrode 146 and drain electrode 147 of the thin film transistor. The semiconductor layer 141 can be disposed below the data pad 149.

As such, since the gate pad 148 is also made of a material with low reflection characteristics, it is possible to prevent image quality from being degraded due to external light reflection in the pad region PA.

An interlayered insulating layer 134 can be formed on the thin film transistor and in the subpixel SP and the pad region PA, and a first insulating layer 136 can be formed on the interlayered insulating layer 134. The interlayered insulating layer 134 can be formed of a single layer or multiple layers using an inorganic material such as silicon nitride (SiNx) or silicon oxide (SiOx), but not limited thereto. The first insulating layer 136 can be made of an organic insulating material, for example, at least one of BCB (benzocyclobutene), acryl resin, epoxy resin, phenolic resin, polyamide resin, and polyimide resin, but not limited thereto.

A common electrode 152 can be formed on the first insulating layer 136 in the subpixel SP. The common electrode 152 can be formed approximately throughout the subpixel SP, e.g., as discussed above in reference to FIG. 3. The common electrode 152 can be made of a transparent metal oxide such as ITO (Indium Tin Oxide) or IZO (Indium Zinc Oxide), but not limited thereto.

A second insulating layer 138 can be formed on the first insulating layer 136 on which the common electrode 152 is formed, and covers the common electrode 152. The second insulating layer 138 can be formed of an inorganic insulating material such as SiOx or SiNx, but not limited thereto.

Pixel electrodes 154 can be disposed on the second insulating layer 138 of the subpixel SP. The pixel electrodes 154 can be configured in a strip shape with a set width and be arranged to be spaced apart from each other by a certain distance, e.g., as discussed above in reference to FIG. 3. The pixel electrode 154 can be electrically connected to the drain electrode 147 of the thin film transistor exposed through the first contact hole CH1 formed in the interlayered insulating layer 134, the first insulating layer 136, and the second insulating layer 138, and can be supplied with an image signal through the thin film transistor. The pixel electrode 154 can be made of a transparent metal oxide such as ITO (Indium Tin Oxide) or IZO (Indium Zinc Oxide), but not limited thereto.

In addition, a second contact hole CH2 can be formed in the gate insulating layer 132, the interlayered insulating layer 134, the first insulating layer 136, and the second insulating layer 138 over the gate pad 148 of the pad area PA. A first transparent conductive layer 156 can be formed in the second contact hole CH2.

Further, a third contact hole CH3 can be formed in the interlayered insulation layer 134, the first insulation layer 136, and the second insulation layer 138 over the data pad 149 of the pad area PA. A second transparent conductive layer 157 can be formed in the third contact hole CH3.

A liquid crystal layer 170 can be formed between the first substrate 121 and the second substrate 131 with the various layers formed thereon as discussed above. A first alignment layer can be formed on the color filter layer 126 of the first substrate 121, and a second alignment layer can be formed on the second insulating layer 138 and the pixel electrode 154 of the second substrate 131. Thus, the liquid crystal molecules of the liquid crystal layer 170 can be aligned along the alignment directions of the first and second alignment layers.

As described above, in the display apparatus 100 according to the first embodiment of the present invention, the lower layer 144a of the gate electrode 144 can be formed of a composite material of (a) a metal with good absorptance such as Mo or MoOx and (b) a ceramic material with good etching characteristics such as Nb2O5, so that the reflection of external light by the gate electrode 144 can be addressed and minimized effectively.

In addition, in the display apparatus 100 according to the first embodiment of the present invention, the metal layer 143 with the low reflection characteristics can be disposed below the data line 142, so that image quality degradation associated with the reflection of external light can be more effectively prevented or minimized. For example, in the case of a 27-inch display apparatus 100 of the present invention, a reflectance of external light can decrease from about 7.5% to 6.3%.

In addition, according to an aspect of the present invention, in some parts of the display apparatus, the semiconductor layer 145 and the gate insulating layer 132 in the subpixel SP are removed in order to place the data line 142 directly on the upper surface of the metal layer 143, so that the metal layer 143 is electrically connected to the data line 142. Thus, a parasitic capacitance that can occur if the semiconductor layer 145 and the gate insulating layer 132 were to be disposed between the metal layer 143 and the data line 142 is not generated, thereby preventing signal delay due to the parasitic capacitance.

In addition, according to an aspect of the present invention, since the gate insulating layer 132 in the subpixel SP is removed (e.g., the gate insulating layer 132 is not present in the portion of the subpixel SP corresponding to the color filter area between the black matrixes), light absorption by the gate insulating layer 132 does not occur. As a result, light transmittance of the display apparatus can be improved. For example, in the case of the 27-inch display apparatus of the present invention, the light transmittance of the display apparatus can increase from 3.47% to 3.52%.

In addition, according to an aspect of the present invention, the data line 142 is formed on the upper surface of the metal layer 143, which means that a thickness of a signal line can be viewed as increased (e.g., in combination with the metal layer 143). Therefore, as the thickness of the data line 142 increases, a resistance of the data line 142 is decreased, which can improve the overall performance of the display apparatus.

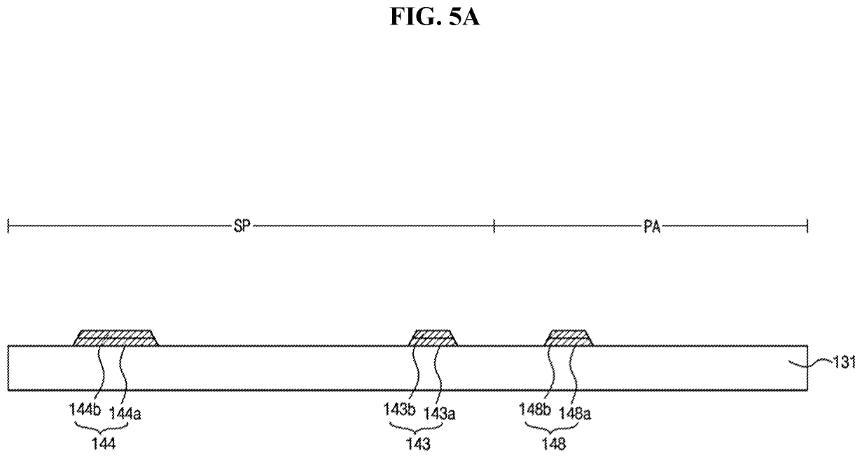

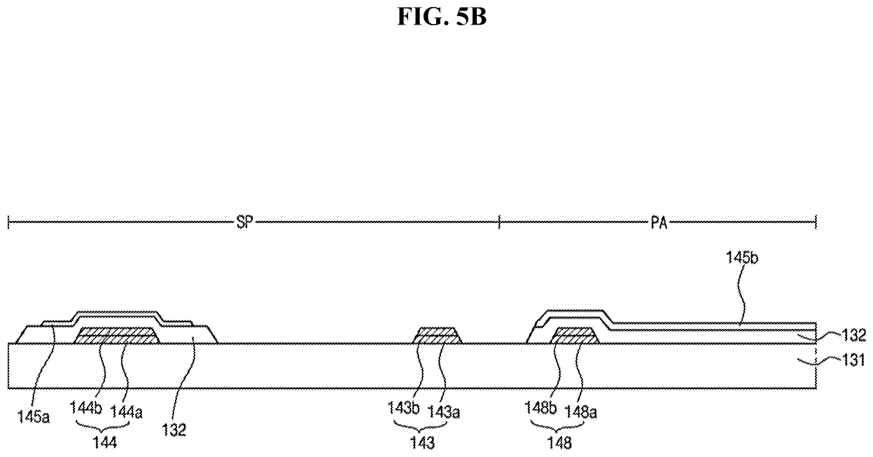

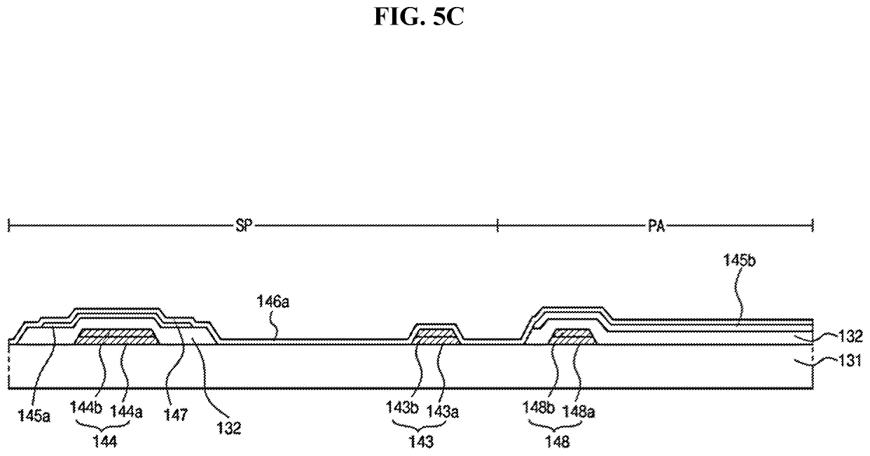

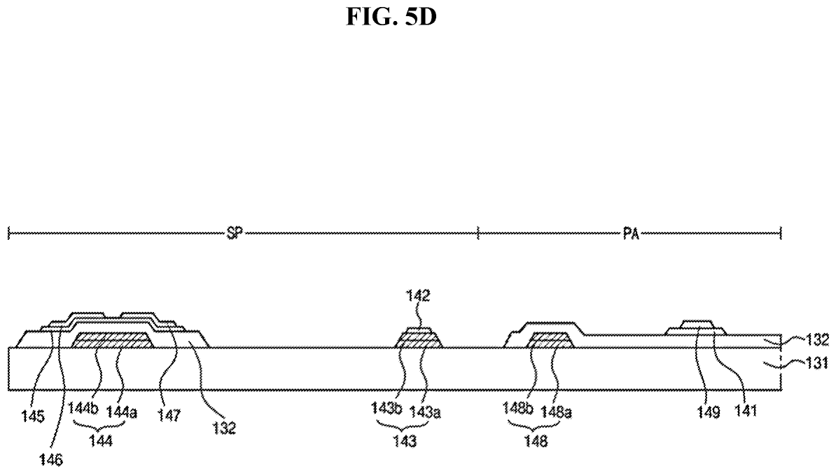

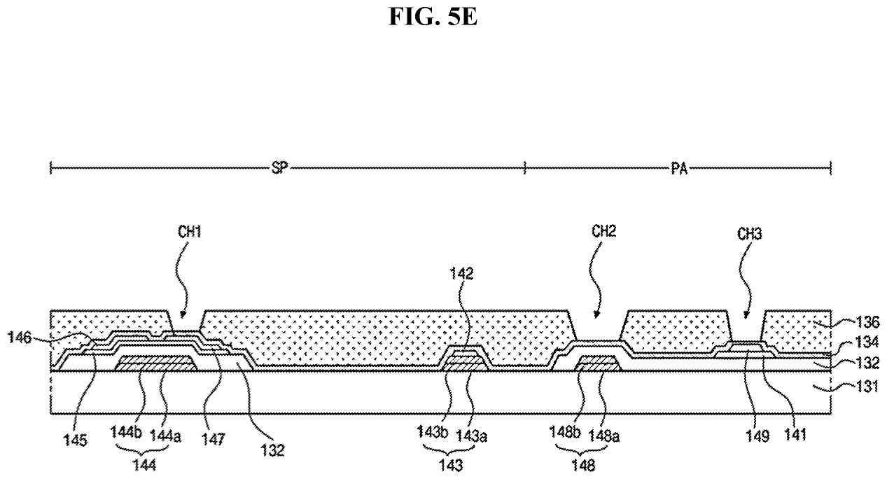

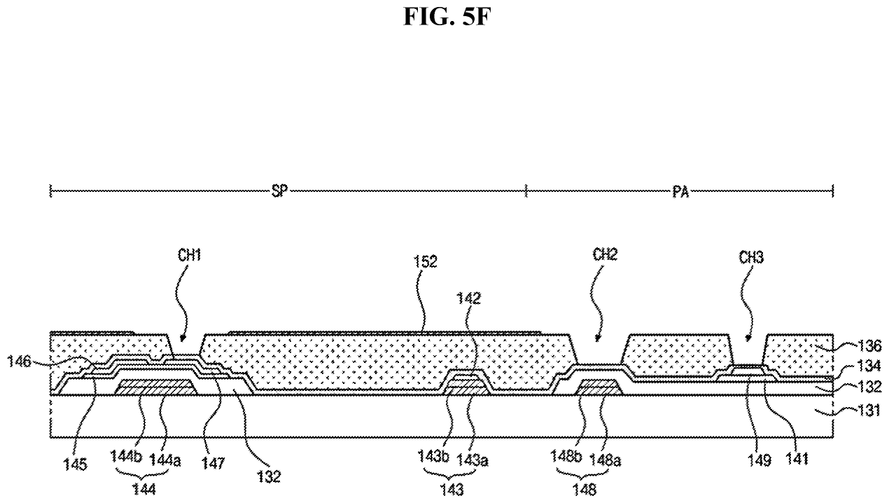

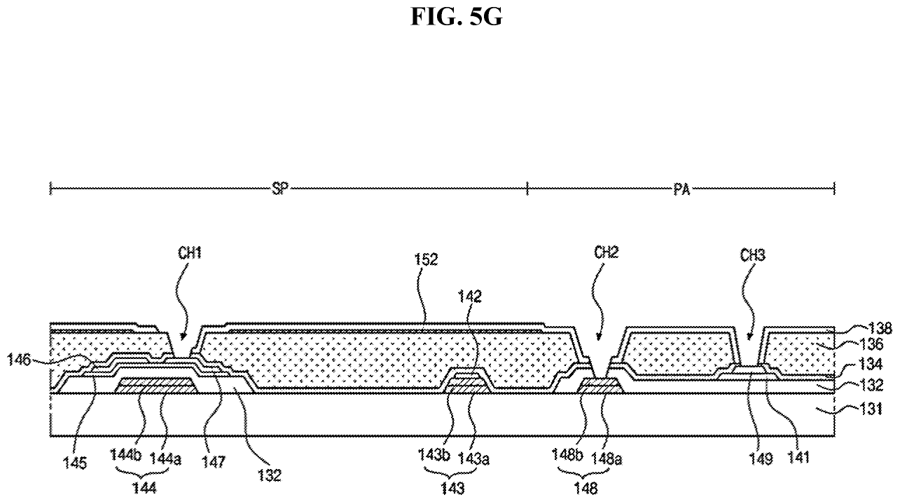

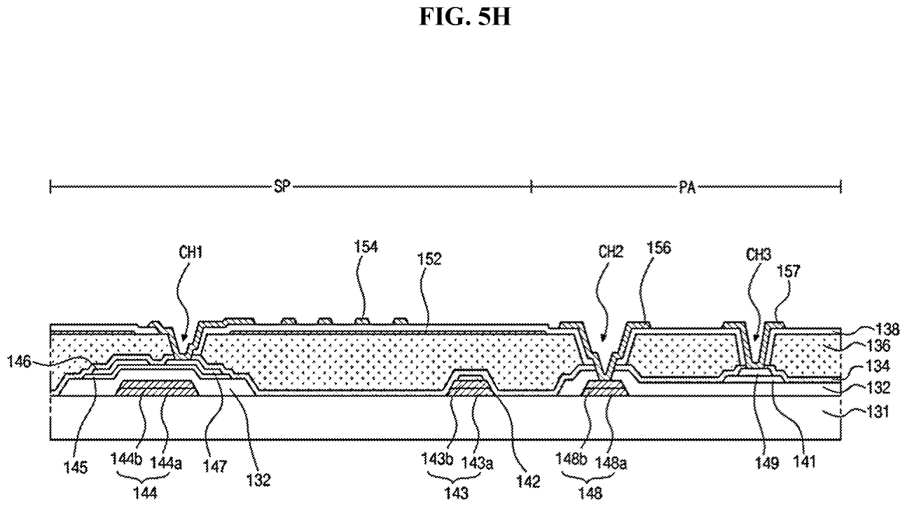

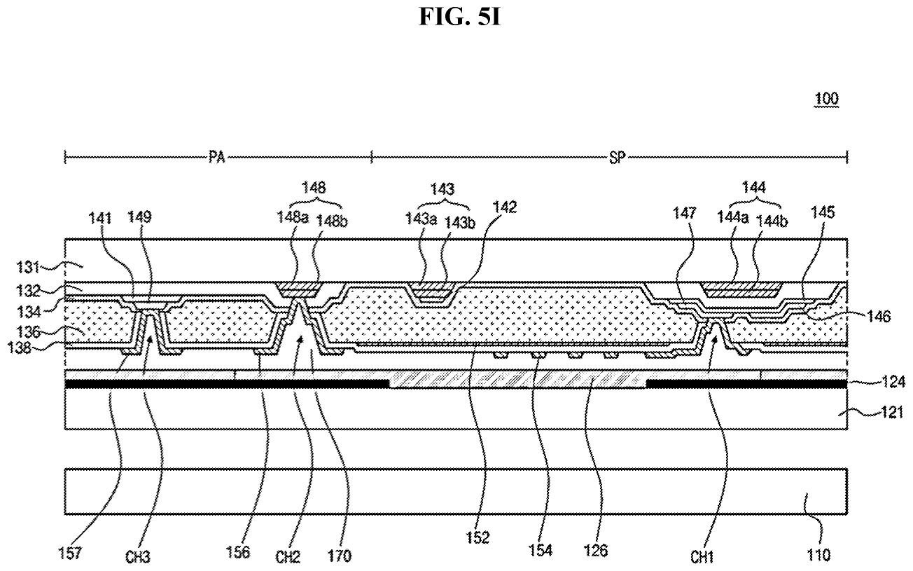

FIGS. 5A to 5I are views illustrating a method of manufacturing a display apparatus according to the first embodiment of the present invention. For instance, the method of FIGS. 5A to 5I can be used to manufacture the display apparatus 100 of FIG. 4, or other display apparatus. One subpixel is focused merely as an example in these figures, and the display apparatus 100 includes the plurality of subpixels having such configuration.

First, as shown in FIG. 5A, in this example, both (a) a composite material of a metal such as Mo or MoOx and a ceramic material such as Nb2O5, and (b) a metal such as aluminum (Al), gold (Au), silver (Ag), or copper (Cu) can be laminated at a thickness of about 4000˜6000 Å and at a thickness of about 300˜500 Å, respectively, throughout the second substrate 131. For instance, the (a) composite material is disposed on the second substrate 131 while the (b) metal is disposed on the (a) composite material. Then these laminated materials are etched using a photolithography to form the gate electrode 144 composed of the first gate metal layer 144a and the second gate metal layer 144b, and the metal layer 143 composed of the first metal layer 143a and a second metal layer 143b on the upper surface of the second substrate 131 of the subpixel SP. For example, the (a) composite material forms the first gate metal layer 144a and the first metal layer 143a, while the (b) metal forms the second gate metal layer 144b and the second metal layer 143b.

At the same time, the gate pad 148 composed of the first gate pad layer 148a and a second gate pad layer 148b can be formed in the pad region PA. For instance, the (a) composite material forms the first gate pad layer 148a, while the (b) metal forms the second gate pad layer 148b. All these layers 144, 143, 148 can be formed in the same process using the same materials.

Subsequently, as shown in FIG. 5B, an insulating material made of SiNx or SiOx, and amorphous silicon can be laminated at a thickness of about 4000˜6000 Å and at a thickness of about 1300˜1900 Å, respectively, by a CVD (Chemical Vapor Deposition) method. Then the laminated insulating material and amorphous silicon of the subpixel SP excluding portions over the gate electrode 144 can be etched to form the gate insulating layer 132 and the semiconductor patterns 145a and 145b covering the gate electrode 144 and the gate pad 148. Here, the insulating material and/or the amorphous silicon material does not cover the metal layer 143 in the subpixel SP.

Then, as shown in FIG. 5C, at least one of molybdenum (Mo), aluminum (Al), chromium (Cr), gold (Au), titanium (Ti), nickel (Ni), neodymium (Nd), and copper (Cu) can be laminated at a thickness of about 4000˜6000 Å to form a metal layer 146a configured with at least one layer. For example, the metal layer 146a covers the entire formed substrate both in the subpixel SP and the pad region PA.

Subsequently, as shown in FIG. 5D, after etching the metal layer 146a, the semiconductor patterns 145a and 145b can be etched using the etched metal layer as a mask layer to form the semiconductor layer 145, the source electrode 146, the drain electrode 147, and the data line 142 in the subpixel SP, and the semiconductor layer 141 and the data pad 149 in the pad region PA.

Then, as shown in FIG. 5E, an inorganic material such as SiNx or SiOx can be laminated at a thickness of about 1300˜1900 Å over the entire formed second substrate 131, and an organic material can be laminated at a thickness of about 24000˜28000 Å on the inorganic material to form the interlayered insulating layer 134 and the first insulating layer 136. Then the first insulating layer 136 on the drain electrode 146, the gate pad 148, and the data pad 149 can be etched.

Next, as shown in FIG. 5F, a transparent metal oxide such as ITO or IZO can be laminated on the first insulating layer 136 and then etched to form the common electrode 152.

Then, as shown in FIG. 5G, an inorganic material such as SiOx or SiNx can be laminated at a thickness of about 3000˜4000 Å on the subpixel SP and the pad region PA. Then the second insulating layer 138 on the drain electrode 147, the gate pad 148, and the data pad 149 can be etched. When etching the second insulating layer 138 on the drain electrode 147, the gate pad 148 and the data pad 149, the interlayered insulating layer 134 and the gate insulating layer 132 can be etched to form the first, second, and third contact holes CH1, CH2, and CH3 exposing the drain electrode 147, the gate pad 148, and the data pad 149, respectively.

Subsequently, as shown in FIG. 5H, a transparent metal oxide such as ITO or IZO can be laminated on the second insulating layer 138 and etched to form the strip-shaped pixel electrode 154 connected to the drain electrode 147 through the first contact hole CH1 in the subpixel SP, and to form the first transparent conductive layer 156 and the second transparent conductive layer 157 in the second contact hole CH2 and the third contact hole CH3 of the pad region PA, respectively.

Then, as shown in FIG. 5I, after forming the black matrix 124 and the color filter layer 126 on the first substrate 121, the first substrate 121 and the second substrate 131 of FIG. 5H can be bonded to each other, and then the liquid crystal layer 170 can be formed between the first substrate 121 and the second substrate 131, thereby completing the display apparatus according to an example of the present invention. The backlight unit 110 can be disposed in the display apparatus.

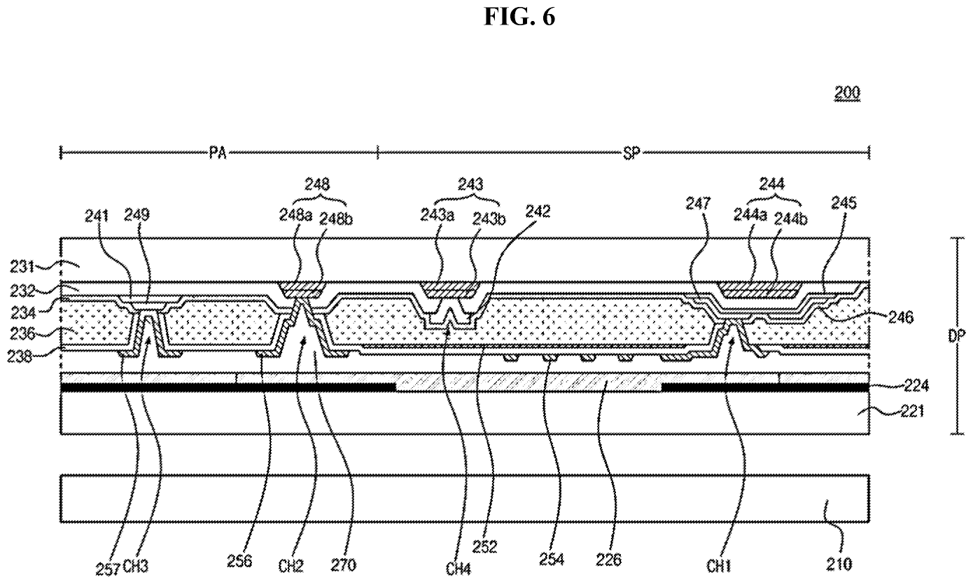

FIG. 6 is a cross-sectional view illustrating a structure of a display apparatus according to a second embodiment of the present invention. Description of the aspects of the second embodiments having the same configuration as the first embodiment of FIG. 4 can be omitted or briefly provided, along other configuration provided below in detail.

As shown in FIG. 6, a display apparatus 200 according this embodiment can include a display panel DP including a subpixel SP and a pad region PA outside/adjacent to the subpixel SP, and a backlight unit 210. The backlight unit 210 can be disposed below the display panel DP and supply light to the display panel DP. In the same way as the first embodiment, the display panel DP includes a plurality of such subpixels SP, and the same or similar descriptions associated with the display panel DP of the display apparatus 100 can be applied in the display apparatus 200.

The display panel DP can include a first substrate 221 and a second substrate 231. A black matrix 224 and a color filter layer 226 can be formed on the first substrate 221.

In the subpixel SP of the second substrate 231, a thin film transistor including a gate electrode 244, a gate insulating layer 232 formed on the gate electrode 244, a semiconductor layer 245 formed on the gate insulating layer 232, and a source electrode 246 and a drain electrode 247 formed on the semiconductor layer 245 and spaced apart from each other by a predetermined distance can be formed.

The gate electrode 244 can configured with a first gate metal layer 244a and a second gate metal layer 244b on the first gate metal layer 244a. The first gate metal layer 244a can be made of a low reflective metal material with good light absorptance. For example, the first gate metal layer 244a can be made of a composite material of (i) a metal such as Mo or MoOx and (ii) a ceramic material such as Nb2O5. Here, Mo and MoOx have good absorption characteristics with an extinction coefficient (k) of about 3˜4, but etching characteristics are not good. Therefore, if forming the first gate metal layer 244a with Mo or MoOx only, reflection of external light can be minimized, but since the etching characteristics can be poor, it can be challenging to form the first gate metal layer 244a by patterning the metal. On the other hand, Nb2O5 has poor light absorption characteristics but good etching characteristics.

As such, by combining the metal such as Mo or MoOx and the ceramic material such as Nb2O5 in the present invention, the first gate metal layer 244a with good low reflection characteristics can be formed.

The second gate metal layer 244b can be made of aluminum (Al), gold (Au), silver (Ag), or copper (Cu) with good conductive characteristics, but not limited thereto.

As such, in the display apparatus 200 according to the second embodiment of the present invention, since the lower layer 244a of the gate electrode 244 formed on the second substrate 231 on the side where an image is displayed is made of a material with low reflection characteristics, reflection of external light by the gate electrode 244 can be minimized, thereby preventing deterioration of image quality due to the reflection of external light.

The gate insulating layer 232 can be formed entirely over the second substrate 231. In the first embodiment, the gate insulating layer 132 is formed only in the region (where the thin film transistor is formed) of the subpixel SP and in the pad region PA. In contrast, in the second embodiment, the gate insulating layer 232 can be formed entirely over the subpixel SP and the pad region PA.

A data line 242 can be disposed on the gate insulating layer 232 of the subpixel SP, and a metal layer 243 can disposed below the data line 242 and on the second substrate 231. The data line 242 can be formed of the same material as the source electrode 246 and the drain electrode 247 of the thin film transistor. The metal layer 243 can be configured with a first metal layer 243a and a second metal layer 243b. The first metal layer 243a can be formed of a high absorptive and low reflective material that is the same material as the first gate metal layer 244a, and the second metal layer 243b can be formed of a metal with good conductivity that is the same material as the second gate metal layer 244b.

As such, according to an aspect of the present invention, the metal layer 243 made of Mo or MoOx with low reflection characteristics and Nb2O5 can be formed on the lower surface of the data line 242, so that the metal layer 243 can absorb the external light incident on the data line 242. Thus, the reflection of external light on the data line 242 can be minimized, thereby preventing degradation of image quality due to the reflection of external light.

Further, in the first embodiment, the gate insulating layer 132 is not formed in the subpixel SP, so the data line 142 is formed directly on the upper surface of the metal layer 143. However, in the second embodiment, the gate insulating layer 232 can be formed between the data line 242 and the metal layer 243.

Here, when the gate insulating layer 232 is disposed between the data line 242 and the metal layer 243, and if the data line 242 and the metal layer 243 are not connected to each other, then a parasitic capacitance can be produced between the data line 242 and the metal layer 243. As a result, a signal delay can occur due to the parasitic capacitance, and the signal delay can cause or contribute to a defect in the display apparatus 200.

To address this issue, in the second embodiment, a fourth contact hole CH4 can be formed in the gate insulating layer 232 between the data line 242 and the metal layer 243, so that the data line 242 and the metal layer 243 contact each other and are electrically connected to each other. Thus, it is possible to prevent the occurrence of parasitic capacitance.

In addition, unlike the first embodiment, the gate insulating layer 232 can be formed on the entire surface of the second substrate 231 excluding portions where the contact holes are formed. Thus, an influence of ions or the like, which can be generated from the second substrate 231, on the data line 242, the common electrode 252, and the pixel electrode 254 can be minimized and effectively addressed.

Further, a gate pad 248 and a data pad 249 can be disposed in the pad region PA. The gate pad 248 can be formed on the upper surface of the second substrate 231, and the data pad 249 is formed on the gate insulating layer 232. The gate pad 248 can be formed of a first gate pad layer 248a and a second gate pad layer 248b. The first gate pad layer 248a can be formed of the same material and in the same process as the first gate metal layer 244a and the first metal layer 243a, and the second gate pad layer 248b can be formed of the same material and in the same process as the second gate metal layer 244b and the second metal layer 243b.

The data pad 249 in the pad region PA can be formed of the same metal and in the same process as the source electrode 246 and the drain electrode 247 of the thin film transistor. A semiconductor layer 241 can be disposed below the data pad 249. As such, since the gate pad 248 is also made of a material with low reflection characteristics, it is possible to prevent image quality from being degraded due to external light reflection in the pad region PA.

Furthermore, an interlayered insulating layer 234 can be formed on the thin film transistor and in the subpixel SP and the pad area PA, and a first insulating layer 236 can be formed on the interlayered insulating layer 234. A common electrode 252 can be formed on the first insulating layer 236 in the subpixel SP. The common electrode 252 can be formed approximately over the entire subpixel SP, and a second insulating layer 238 can be formed on the first insulating layer 236 on which the common electrode 252 is formed and cover the common electrode 252.

Pixel electrodes 254 can be disposed on the second insulating layer 238 of the subpixel SP. The pixel electrodes 254 can be configured in a strip shape with a set width and be arranged to be spaced apart from each other by a certain distance. The pixel electrode 254 can be electrically connected to the drain electrode 247 of the thin film transistor exposed through the first contact hole CH1 formed in the interlayered insulating layer 234, the first insulating layer 236, and the second insulating layer 238, and can be supplied with an image signal through the thin film transistor. The contact holes CH1-CH3 are similarly disposed in this embodiment.

Further, the other elements of the display apparatus 200 such as a first transparent conductive layer 256, a second transparent conductive layer 257, a black matrix 224, a color filter layer 226, a liquid crystal layer 270, a first substrate 221, a backlight unit 210, etc. are formed in the same or similar manner as the first embodiment, which is described above.

As a variation, the display apparatus 100, 200 can be a different type of display, such as an organic light emitting display device, a quantum dot display device, etc. In such cases, the backlight unit is not needed.

According to an aspect of the present invention, a display apparatus includes a display panel including a first substrate and a second substrate; a color filter layer disposed on the first substrate; a plurality of gate lines and a plurality of data lines disposed on the second substrate to define a plurality of subpixels; a thin film transistor disposed in each of the plurality of subpixels on the second substrate; a common electrode and a pixel electrode disposed in each of the plurality of subpixels; and a light absorption layer disposed below each data line to absorb light incident from outside.

According to an aspect of the present invention, a display apparatus includes a substrate including a subpixel region and a pad region adjacent to the subpixel region; a subpixel disposed in the subpixel region; a light absorption layer and a gate electrode of the subpixel separated from each other, and disposed in the subpixel region of the substrate; a data line disposed on the light absorption layer; and a gate pad separated from the light absorption layer, and disposed in the pad region of the substrate, wherein the gate electrode, the light absorption layer and the gate pad are formed of a same material in a same process, and wherein each of the gate electrode, the light absorption layer and the gate pad includes a first metal layer and a second metal layer disposed on the first metal layer.

As described above, according to an aspect of the present invention, since the array substrate on which the thin film transistor is formed is disposed on the side where an image is displayed, an area of the bezel can be minimized.

In addition, according to an aspect of the present invention, since the lower layer of the gate electrode formed on the second substrate on the side where an image is displayed is made of a low reflective material, reflection of external light by the gate electrode can be minimized, and thus deterioration of image quality due to the reflection of external light can be prevented.

In addition, according to an aspect of the present invention, since the metal layer with low reflection characteristics is formed on the lower surface of the data line, the metal layer can absorb the external light incident on the data line to minimize the reflection of external light on the data line. As a result, deterioration of image quality due to the reflection of external light can be prevented.

In addition, according to an aspect of the present invention, power consumption can be reduced by low reflection, so that it possible to implement a low-power display apparatus.

Although the embodiments of the present invention are described above in more detail with reference to the accompanying drawings, the present invention is not necessarily limited to these embodiments, and can be variously modified and implemented without departing from the technical idea of the present invention. Therefore, the embodiments disclosed in the present invention are not intended to limit the technical idea of the present invention, but to explain, and the scope of the technical idea of the present invention is not limited by these embodiments. Therefore, it should be understood that the embodiments described above are illustrative in all respects and not restrictive. The protection scope of the present invention can be construed according to the scope of the claims, and all technical ideas within the scope equivalent thereto should be construed as being included in the scope of the present invention.

What is claimed is:

1. A display apparatus, comprising:
a display panel including a first substrate and a second substrate;
a color filter layer disposed on the first substrate;
a plurality of gate lines and a plurality of data lines disposed on the second substrate to define a plurality of subpixels;
a thin film transistor disposed in each of the plurality of subpixels on the second substrate;
a common electrode and a pixel electrode disposed in each of the plurality of subpixels; and
a light absorption layer disposed below each data line to absorb light incident from outside.

2. The display apparatus of claim 1, wherein the light absorption layer includes:
a first metal layer having an extinction coefficient (k), where 0.6<k<1.2; and
a second metal layer disposed on the first metal layer.

3. The display apparatus of claim 2, wherein the first metal layer includes a composite material composed of a metal and a ceramic material.

4. The display apparatus of claim 3, wherein the metal of the first metal layer includes Mo or MoOx, and
wherein the ceramic material of the first metal layer includes Nb2O5.

5. The display apparatus of claim 1, wherein the light absorption layer is in a floating state.

6. The display apparatus of claim 4, wherein the thin film transistor includes:
a gate electrode disposed on the second substrate;
a gate insulating layer disposed on the gate electrode;
a semiconductor layer disposed on the gate insulating layer; and
a source electrode and a drain electrode disposed on the semiconductor layer.

7. The display apparatus of claim 6, wherein the gate insulating layer is excluded in a region where the data line is formed.

8. The display apparatus of claim 7, wherein the data line is disposed directly on an upper surface of the light absorption layer.

9. The display apparatus of claim 6, wherein the gate insulating layer is formed entirely over the subpixel and covers a part of the light absorption layer that is disposed under the data line.

10. The display apparatus of claim 9, wherein the data line and the light absorption layer in each subpixel are disposed with the gate insulating layer interposed therebetween.

11. The display apparatus of claim 10, wherein the data line and the light absorption layer in each subpixel are electrically connected to each other through a contact hole formed in the gate insulating layer.

12. The display apparatus of claim 4, further comprising:
a pad region disposed adjacent to the subpixel and including a gate pad and a data pad.

13. The display apparatus of claim 12, wherein the gate pad is formed of a same material as the light absorption layer.

14. The display apparatus of claim 1, further comprising:
a backlight unit facing the first substrate and configured to supply light to the display panel.

15. A display apparatus, comprising:
a substrate including a subpixel region and a pad region adjacent to the subpixel region;
a subpixel disposed in the subpixel region;
a light absorption layer and a gate electrode of the subpixel separated from each other, and disposed in the subpixel region of the substrate;
a data line disposed on the light absorption layer; and
a gate pad separated from the light absorption layer, and disposed in the pad region of the substrate,
wherein the gate electrode, the light absorption layer and the gate pad are formed of a same material in a same process, and
wherein each of the gate electrode, the light absorption layer and the gate pad includes a first metal layer and a second metal layer disposed on the first metal layer.

16. The display apparatus of claim 15, wherein the first metal layer includes a composite material composed of a metal and a ceramic material.

17. The display apparatus of claim 15, wherein a thickness of the first metal layer is about 4000-6000 Å, and a thickness of the second metal layer is about 300-500 Å.

18. The display apparatus of claim 15, further comprising:
a gate insulating layer covering the gate electrode and the gate pad, but not covering the light absorption layer.

19. The display apparatus of claim 15, further comprising:
a gate insulating layer covering the entire gate electrode, a portion of the light absorption layer. and a portion of the gate pad.

20. The display apparatus of claim 19, wherein the data line contacts the light absorption layer via a contact hole formed in the gate insulating layer.
